(19) United States
(12) Patent Application Publication
(10) Pub. No.: US 2002/0093083 A1
(43) Pub. Date: Jul. 18, 2002

(54) Integrated circuit with identification circuit and method for checking a connection situation of a bonding pad

(76) Inventors: Martin Brox, Munchen (DE); Helmut Schneider, Munchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/053,027

(22) Filed: Jan. 18, 2002

(30) Foreign Application Priority Data
Jan. 18, 2001 (DE) 101 02 000.7

(51) Int. Cl. H01L 23/02

(52) U.S. Cl. 257/678

(57) ABSTRACT

A description is given of an integrated circuit having components and a method for checking a connection configuration of bonding pads. The integrated circuit has an identification circuit that identifies a connection of the bonding pads to external circuits. After the identification of the connected bonding pads, the data width of the input/output circuit is preferably programmed accordingly. In this way, self-detection and automatic programming are possible without data inputting from the outside.

### BACKGROUND OF THE INVENTION

### FIELD OF THE INVENTION

The invention relates to an integrated circuit having components for acquiring, processing and storing data. Bonding pads are connected to the components and serve for a signal exchange between the components and an external circuit.

Integrated circuits are fabricated on a semiconductor material and incorporated as a semiconductor chip into a housing. The semiconductor chip has bonding pads to which the components of the integrated circuit are electrically connected. The bonding pads are electrically connected to connection pins of the housing via bonding wires. External circuits via which the components of the integrated circuit exchange signals are connected via the connection pins. The bonding pads are additionally used for outputting and reading in data, the data width with which the data are exchanged are dependent on how many connection pins are present. Thus, the situation can arise where the number of bonding pads present exceeds the number of connection pins of the housing. Consequently, after the incorporation of the integrated circuit into the housing, only some of the bonding pads are connected to connection pins. Thus, it is also the case that only some of the bonding pads are available for a data exchange.

It is known in this case to provide a further or a plurality of further bonding pads which is or are used for programming the number of bonding pads available for the data exchange. However, the advancing miniaturization of the components requires a more compact embodiment.

### SUMMARY OF THE INVENTION

It is accordingly an object of the invention to provide an integrated circuit with an identification circuit and a method for checking a connection situation of a bonding pad which overcome the above-mentioned disadvantages of the prior art devices and methods of this general type, which manages with fewer bonding pads. A further object of the invention relates to providing a method and an apparatus for checking the occupancy of a bonding pad.

With the foregoing and other objects in view there is provided, in accordance with the invention, an integrated circuit. The circuit contains components for acquiring, processing and storing data, and bonding pads connected to the components and serve for exchanging signals between the components and an external circuit. A control unit is provided for controlling a supply of a charge or a voltage to a respective bonding pad of the bonding pads. A detection circuit is connected to the respective bonding pad. The detection circuit detects the voltage or the charge on the respective bonding pad. The detection circuit compares the voltage or the charge detected with a predetermined value and identifies whether the respective bonding pad is connected to the external circuit.

One advantage of the invention is that the integrated circuit has an identification circuit that automatically identifies a connection of the bonding pad to an external circuit. Consequently, it is not necessary for the integrated circuit to be programmed externally via an additional bonding pad or a separate connection pin with regard to the occupancy of the bonding pads.

Subsequently, it is necessary to distinguish whether the circuit is connected to a terminated or a non-terminated bus system. In a terminated bus system, each connection pin via which data inputting or outputting takes place is connected to a terminating voltage of value Vtt via a terminating resistor of value Rtt. The terminating resistor is absent in a non-terminated bus system.

We will first consider the situation of the non-terminated system. In this case, it is furthermore advantageous that, through the application of a charge to the bonding pad and subsequent checking of the voltage, the integrated circuit identifies whether the bonding pad is connected to an external circuit. A simple method for checking a connection of a bonding pad to an external circuit is thus provided.

Preferably, the identification circuit checks the temporal development of the voltage and, from the temporal gradient, identifies a connection of an external circuit. As a result, the identification of a connection is independent of the voltage state of the bonding pad. Consequently, the checking can be used diversely without having to await a defined voltage state of the bonding pad.

A preferred embodiment has a current or voltage source that is connected to the bonding pad via a switch. In this case, at the beginning of the detection, the bonding pad is brought to a specific voltage, preferably the ground potential 0 V. Furthermore, the identification circuit has a detection circuit, which monitors the voltage on the bonding pad and identifies a connection of the bonding pad through a comparison of the monitored voltage with a predetermined voltage. After the identification of a connection of the bonding pad, the detection circuit outputs an identification signal via an output. This embodiment is constructed in a simple manner and functions reliably.

Preferably, the bonding pad is provided with a defined charge at a predetermined instant, and then the temporal development of the voltage is detected and compared with a predetermined scheme or pattern. From the comparison, the detection circuit identifies whether a bonding pad is connected to an external circuit. Prescribing a defined charge onto the bonding pad enables a very precise measurement method and hence precise identification of the type of connection of the bonding pad.

In a further preferred embodiment, a control circuit is provided, which controls the switch and the detection circuit and thus ensures a precise temporal sequence of the measurement method. The measurement accuracy of the method is thus increased.

Preferably, a plurality of schemes or patterns are predetermined, which correspond to a predetermined connection configuration of the bonding pad.

Preferably, the output signal of the detection circuit is used for defining the bonding pads via which data are exchanged between the integrated circuit and external circuits. Many of the basic concepts can be adopted in a terminated bus system. It is merely not expedient to apply a charge with a current source. In a preferred embodiment, therefore, a voltage that differs from Vtt is connected to the bonding pad via a switchable connection having a sufficiently high resistance (R>Rtt). After the production of the connection, it is then possible to carry out a simple evaluation of the voltage on the bonding pad, since only when the bonding pad is connected to a connection pin is the voltage on the bonding pad approximately equal to Vtt.

All the embodiments regarding detection circuits and temporal control that were presented for non-terminated bus systems are maintained for the case of the terminated bus, too.

In accordance with an added feature of the invention, the detection circuit has a signal input connected to the control circuit. The control circuit is further connected to the switch, the control circuit controls the switch and prescribes a clock signal to the detection circuit.

In accordance with a further feature of the invention, the detection circuit has an output and is further coupled to a predetermined number of the bonding pads, through which the data can be exchanged with a number of external circuits. An input/output circuit controlling an outputting and reception of the data is connected to the bonding pads. A further control unit is connected to the output of the detection circuit. The further control unit is connected to the input/output circuit, the further control unit adapts a data width with which the data are output from the input/output circuit through the bonding pads to the number of the bonding pads that have been identified as occupied.

With the foregoing and other objects in view there is provided, in accordance with the invention, a method for checking a connection configuration of bonding pads of an integrated circuit. The bonding pads are connected to components of the integrated circuit and serve for connecting to external circuits, and the bonding pads receive and output signals. The method includes the steps of supplying a charge or a voltage to a respective bonding pad; and determining that the respective bonding pad is connected to one of the external circuits from a measured charge or a measured voltage at the respective bonding pad.

In accordance with another mode of the invention, there are the steps of detecting a temporal development of the voltage or the charge at the respective bonding pad; comparing the temporal development with a comparison pattern; and ascertaining an existence of a connection of the respective bonding pad to the external circuit from comparison results.

In accordance with an additional mode of the invention, there are the steps of checking a predetermined number of the bonding pads for a connection to one of the external circuits; and carrying out a data exchange through the bonding pads which have been identified as being connected to one of the external circuits.

Other features which are considered as characteristic for the invention are set forth in the appended claims.

Although the invention is illustrated and described herein as embodied in an integrated circuit with an identification circuit and a method for checking a connection situation of the bonding pad, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic illustration of an integrated circuit incorporated in a housing according to the invention;

FIG. 2 is a block diagram of a bonding pad which is connected to an external circuit on a non-terminated data bus;

FIG. 3 is a graph showing a voltage profile for a connected and a non-connected bonding pad with a non-terminated data bus;

FIG. 4 is a block diagram of the integrated circuit with a control unit and a data input/output circuit;

FIG. 5 is a block diagram of the external circuit with a terminated data bus; and

FIG. 6 is a graph of a voltage profile for a connected and a non-connected bonding pad with a terminated data bus.

### DESCRIPTION OF THE PREFERRED EMBODIMENTS

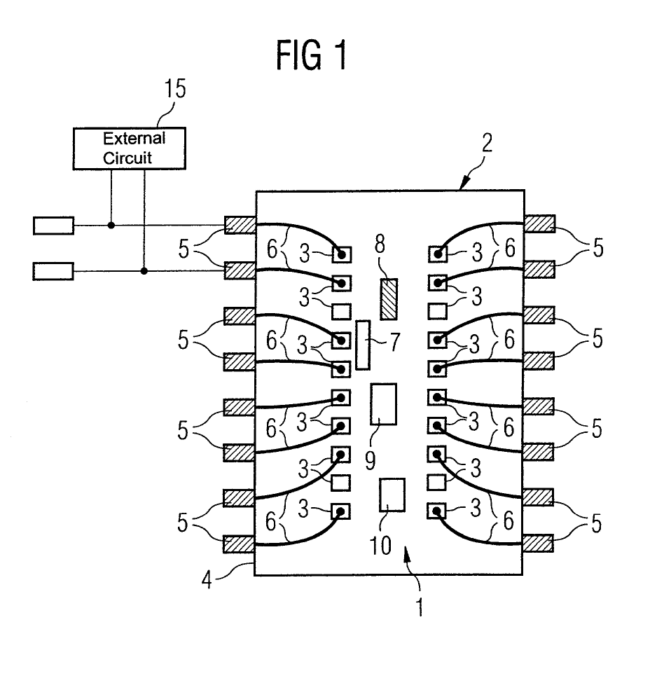

In all the figures of the drawing, sub-features and integral parts that correspond to one another bear the same reference symbol in each case. Referring now to the figures of the drawing in detail and first, particularly, to FIG. 1 thereof, there is shown an integrated circuit 1 applied on a semiconductor substrate 2. By way of example, a logic circuit 8, a digital circuit 9, driver circuits 10 and a memory module 7, are provided as components of the integrated circuit 1. Furthermore, the semiconductor substrate 2 has bonding pads 3. The Bonding pads 3 constitute so-called bonding islands which are connected to connection pins 5 of a housing 4 via bonding wires 6, the housing 4 receiving the semiconductor substrate 2 with the integrated circuit 1 and protecting it against ambient influences. The housing 4 is usually configured in the form of a closed plastic housing.

The bonding pads 3 are used for the purpose of exchanging data and energy between the integrated circuit 1 and external circuits 15. To that end, the bonding pads 3 are electrically connected to the components of the integrated circuit 1 such as e.g. the memory module 7, the logic circuit 8, the digital circuit 9 and/or the driver circuit 10. In the exemplary embodiment illustrated, the upper two bonding pads 3 are in each case electrically connected via the bonding wire 6 to the connection pin 5 and to the external circuits 15. Consequently, data are exchanged only via the two upper bonding pads 3 in each case, so that corresponding programming of the data input/output circuit is required. Since, depending on the application, the integrated circuit 1 can be incorporated into differently constructed housings 4 with a different number of connection pins 5, it is not expedient to program the e.g. data width, i.e. the number of bonding pads 3 which are used for a data exchange, prior to the incorporation. In further embodiments, by way of example, the address width or the functionality is programmed, as a result of which the occupancy of the bonding pads 3 is defined.

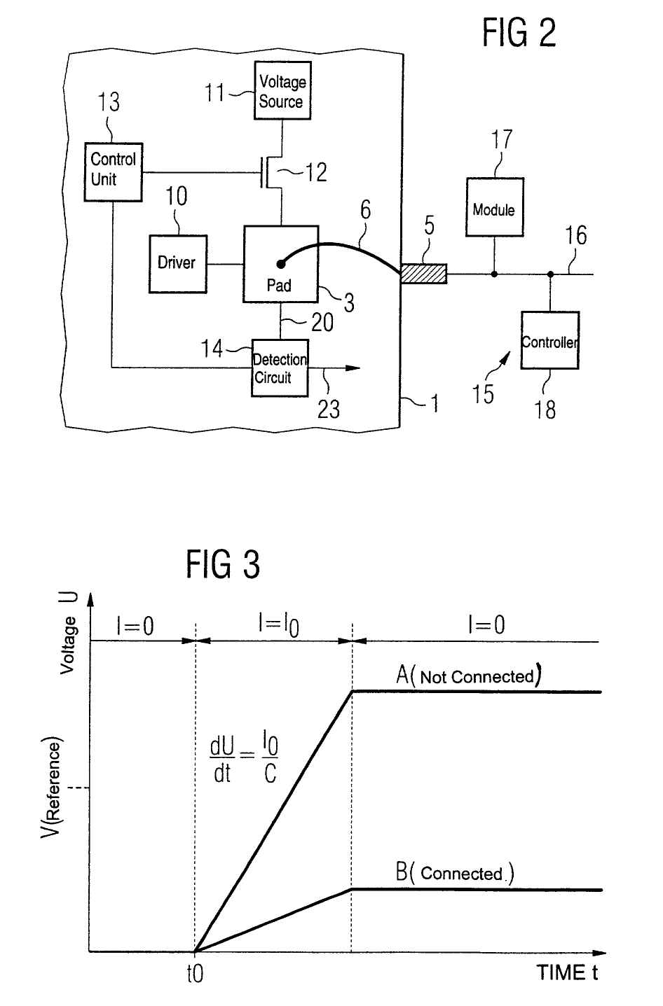

We will first consider once again a circuit for a non-terminated bus system. FIG. 2 shows a detail from the integrated circuit 1 with the bonding pad 3 that is connected via the bonding wire 6 to the connection pin 5 and to the external circuit 15. The integrated circuit 1 has a voltage source 11 that is electrically connected to the bonding pad 3 via a transistor 12. The transistor 12 constitutes a field-effect transistor whose control connection is connected to a control unit 13. The transistor 12 constitutes a switch and can also be configured in any other type of switch. The voltage state at the control connection governs whether or not the voltage source 11 is connected to the bonding pad 3. The voltage state is controlled by the control unit 13. The bonding pad 3 is connected to the driver circuit 10 via an electrical line. The driver circuit 10 controls the data exchange between the integrated circuit 1 and the external circuits. A data bus 16 is electrically connected, e.g. to a further module 17 and a controller 18. Instead of the external circuits 15 illustrated in FIG. 2, it is also possible to provide any other type of external circuits 15.

In the simplest case, the external circuit 15 is a signal line or a data bus 16.

The checking of the bonding pad 3 to ascertain whether or not the bonding pad 3 is connected to an external circuit 15 is effected in the following manner for the non-terminated system. At a predetermined instant t0 (FIG. 3), the control unit 13 closes the connection between the voltage source 11 and the bonding pad 3 via the transistor 12. Afterward, preferably a predetermined quantity of charge is transferred to the bonding pad 3 and then the connection between the voltage source 11 and the bonding pad 3 is interrupted again by the control unit 13.

When the charge transfer begins, the control unit 13 passes a start signal to a detection circuit 14, which is connected to the bonding pad 3 via a first line 20. After receiving the start signal, the detection circuit 14 detects the temporal profile of the voltage present on the bonding pad 3. FIG. 3 shows the temporal development of the voltage on the bonding pad 3 in a line A, which corresponds to the situation wherein the bonding pad 3 is not connected to the external circuit 15. The curve B shows the behavior of the voltage in the case in which the bonding pad 3 is connected to the external circuit 15. A temporal profile of the voltage on the bonding pad 3 essentially depends on whether the bonding pad 3 is connected only to the integrated circuit 1 or also via the connection pin 5 to the external circuit 15. If the external circuit 15 is connected to the bonding pad 3, then the voltage on the bonding pad 3 rises more gently and reaches a smaller maximum value than in the case in which the bonding pad 3 is not connected to the external circuit 15. The reason is that the voltage gradient is inversely proportional to a load capacitance Co.

Consequently, on the basis of the temporal profile of the voltage or on the basis of the maximum voltage reached, the detection circuit 14 detects whether the bonding pad 3 is connected to the external circuit 15.

In a simple embodiment, the detection circuit 14 compares only the voltage reached and compares the voltage with a comparison voltage corresponding to a non-connected bonding pad 3. If the detected voltage lies below the comparison voltage, then a connection of the bonding pad 3 to the external circuit 15 is identified.

In an improved embodiment, the temporal development of the voltage is detected by the detection circuit and compared with comparison values for the temporal development of the voltage that corresponds to a non-connected bonding pad. If the temporal development of the voltage is smaller than the comparison value, then a connected bonding pad is identified. The comparison values are preferably determined empirically and held in a memory connected to the detection circuit 14.

If the detection circuit 14 identifies a connected bonding pad, then the detection circuit 14 outputs an identification signal via an output 23.

The identification signal is used for example for configuring the data width or for defining the bonding pads 3 through which the data exchange is intended to take place.

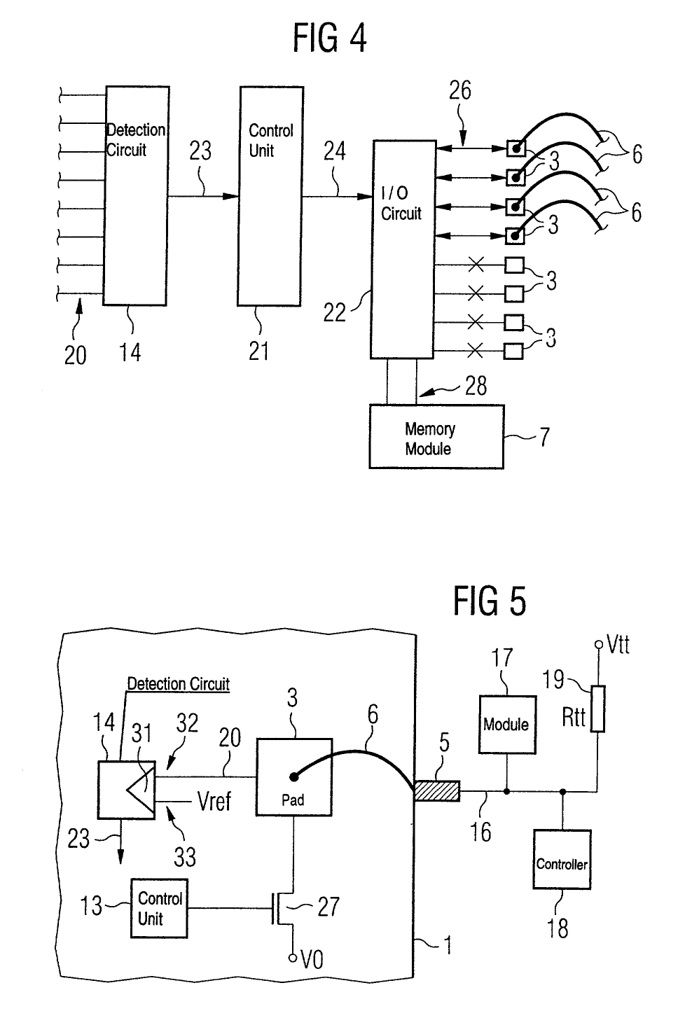

FIG. 4 shows a detail view of the integrated circuit 1 with an input/output circuit 22. The detection circuit 14 is connected to the bonding pads 3 via the first lines 20. Furthermore, the detection circuit 14 is connected to a second control unit 21 via the output 23. The second control unit 21 is in turn connected to an input/output circuit 22 via a control line 24. The input/output circuit 22 is connected to the bonding pads 3 by input/output lines 26. Furthermore, the input/output circuit 22 is connected to the memory module 7 via a second interface 28. The detection circuit 14 checks the bonding pads 3 according to the method described and identifies that, for example, the top four bonding pads 3 are connected to external circuits 15. The detection circuit 14 passes on this information to the second control unit 21 via the output 23. The second control unit 21 passes a corresponding control signal via the control line 24 to the input/output circuit 22. As a consequence of the control signal, the input/output circuit 22 connects only the top four input/output lines 26 to the second interface 28. Consequently, data and/or commands can be exchanged with the memory module 7 only via the top four bonding pads and the top four input/output lines 26.

The programming of the data width or the definition of the bonding pads 3 to be used for the data exchange is effected for example during a reset operation of the integrated circuit 1, during which the voltage supply of the integrated circuit 1 is run up. During the operation, the control unit 13 receives the information that it is necessary to carry out programming of the bonding pads 3 to be defined. Afterward, in the manner described above, the control unit 13 controls the charging of the bonding pad 3 and the detection of the voltage on the bonding pad 3 by use of the detection circuit 14. The detection circuit 14 passes on the result of the checked bonding pads 3 to the second control unit 21, which in turn programs the input/output circuit 22 correspondingly. The control unit 13 and the second control unit 21 can also be embodied as one control unit.

On account of the apparatus described, and the method described, the integrated circuit 1 is able itself to identify a connection configuration of the bonding pads 3 and then itself to perform programming of the data width and definition of the bonding pads 3 to be used for the data exchange, without data inputting from the outside. Consequently, there is no need for a separate bonding pad for programming the data width or for programming the bonding pads 3 to be used for the data exchange.

FIG. 5 shows a further embodiment of the invention, in which the data bus 16 is connected to a supply voltage Vtt via a terminating resistor 19. In this embodiment, the bonding pad 3 is connected to a reference connection V0 via a second transistor 27. A gate connection of the second transistor 27 is connected to the control unit 13, which turns the second transistor 27 on in the event of a measurement operation.

In the embodiment of FIG. 5, a connection of the bonding pad 3 is checked in the now described manner. The control unit 13 closes the second transistor 27, which produces only a weak conductive connection between the bonding pad and a suitable reference potential V0 (e.g. ground). If, as is illustrated in FIG. 5, the bonding pad 3 is connected to the data bus 16 via the connection pin 5, then current flows via the terminating resistance 19, so that the terminating voltage Vtt is present on the data bus 16 and the bonding pad.

In this embodiment, the detection circuit 14 has a differential amplifier 31. Consequently, the terminating voltage Vtt is present at a first input 32 of the differential amplifier 31. A reference voltage Vref is present at a second input 33 of the differential amplifier 31, which reference voltage is preferably chosen in the middle between V0 and Vtt (for V0=0, that is to say Vtt/2). Consequently, the differential amplifier 31 passes a signal to the detection circuit 14 that indicates that the voltage on the bonding pad lies above the reference voltage Vref. As a result, the detection circuit 14 that is connected to the second output of the differential amplifier, identifies that the bonding pad 3 is connected to a terminated data bus 16.

If the bonding pad 3 is not connected to a data bus 16, then the voltage impressed on the bonding pad 3 is equal to the value of the impressed reference potential V0. The reference potential V0 is then smaller, for example, than the reference voltage Vref for the second input of the differential amplifier and the differential amplifier outputs, at the output, the inverted signal in comparison with the case of the connected bonding pad. Consequently, the detection circuit 14 identifies that the bonding pad 3 is not connected to an external circuit 15.

If the bonding pad 3 is to be used in normal operation again, then the control unit 13 opens the transistor 12 or the second transistor 27, so that the bonding pad 3 is isolated from the voltage source 1 or from the supply voltage Vtt.

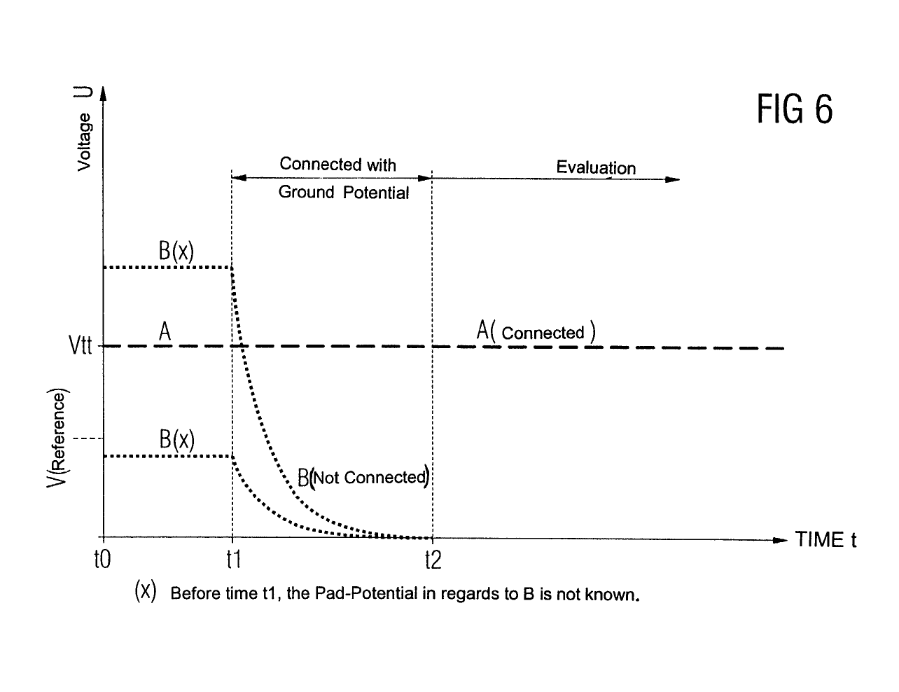

FIG. 6 shows a measurement diagram for the embodiment of FIG. 5, in which the data bus 16 is connected to a terminating voltage Vtt via the terminating resistor 19. At the instant T0, the second transistor 27 is non-conducting and the bonding pad 3 is connected to the data bus 16 via the bonding wire 6. At this instant, a voltage lying in the region of the supply voltage Vtt is present on the bonding pad 3. At the instant T1, the control unit 13 switches the second transistor 27 into a conducting state. Depending on whether or not the connection pin 5 to which the bonding pad 3 is connected via the bonding wire 6 is connected to a data bus 16, the voltage present on the bonding pad 3 changes in accordance with a first and a second signal curve A, B. If the bonding pad 3 is connected to the data bus 16, then approximately the terminating voltage Vtt is present on the bonding pad 3.

If no data bus 16 is connected to the connection pin 5 to which the bonding pad 3 is connected, then the voltage falls after the instant T1 to the value 0 in accordance with the second curve B. In this case, the voltage on the bonding pad 3 may be arbitrary before the instant t since the pad 3 is floating. An evaluation of the voltage present at the first input 32 by the detection circuit preferably takes place only after the second instant T2, in order that the voltage present on the bonding pad 3 can fall to a constant value. This ensures a reliable evaluation of the connection configuration of the bonding pads 3. Comparison values for the voltage and/or the quantity of charge which are established depending on defined connection configurations at the bonding pad 3 were preferably determined empirically for the integrated circuit. On the basis of the comparison values assigned to the defined connection configurations, it is possible for the detection circuit 14 to assign the charge and/or voltage on the bonding pad 3—detected during the measurement operation—to a specific connection configuration of the connection pin 5.

We claim:

1. An integrated circuit, comprising:
components for acquiring, processing and storing data;
bonding pads connected to said components and serve for exchanging signals between said components and an external circuit;
a control unit controlling a supply of a charge or a voltage to a respective bonding pad of said bonding pads; and
a detection circuit connected to said respective bonding pad, said detection circuit detecting the voltage or the charge on said respective bonding pad, said detection circuit comparing the voltage or the charge detected with a predetermined value and identifies whether said respective bonding pad is connected to the external circuit.

2. The integrated circuit according to claim 1, wherein said detection circuit detects a temporal development of the voltage and, from the temporal development, identifies if a connection to the external circuit exists.

3. The integrated circuit according to claim 1,
including a voltage source supplying the voltage or the charge;
including a switch connected between said voltage source and said respective bonding pad, said voltage source supplying said respective bonding pad with the voltage or the charge; and
wherein said detection circuit is connected to said respective bonding pad and monitors the voltage or the charge on said respective bonding pad, said detection circuit having an output and outputs an identification signal if the voltage or the charge corresponds to the predetermined value.

4. The integrated circuit according to claim 3, wherein said voltage source applies a defined charge or a defined voltage to said respective bonding pad at a predetermined instant, said detection circuit has a signal input for receiving a start signal, in that, after receiving the start signal, said detection circuit detects a temporal development of the defined voltage on said respective bonding pad and outputs an identification signal if the temporal development corresponds to a predetermined pattern.

5. The integrated circuit according to claim 4, wherein a plurality of patterns are predetermined, and in that each of the patterns corresponds to a defined connection configuration of said respective bonding pad.

6. The integrated circuit according to claim 3, wherein said detection circuit has a signal input connected to said control circuit, said control circuit is further connected to said switch, said control circuit controlling said switch and prescribes a clock signal to said detection circuit.

7. The integrated circuit according to claim 1,
wherein said detection circuit has an output and is further coupled to a predetermined number of said bonding pads, through which the data can be exchanged with a number of external circuits;
including an input/output circuit controlling an outputting and reception of the data and connected to said bonding pads; and
including a further control unit connected to said output of said detection circuit, said further control unit is connected to said input/output circuit, said further control unit adapts a data width with which the data are output from said input/output circuit through said bonding pads to said number of said bonding pads that have been identified as occupied.

8. A method for checking a connection configuration of bonding pads of an integrated circuit, the bonding pads being connected to components of the integrated circuit and serve for connecting to external circuits, the bonding pads receiving and outputting signals, which comprises the steps of:
supplying one of a charge and a voltage to a respective bonding pad; and
determining that the respective bonding pad is connected to one of the external circuits from a measured charge or a measured voltage at the respective bonding pad.

9. The method according to claim 8, which comprises:
detecting a temporal development of the voltage or the charge at the respective bonding pad;
comparing the temporal development with a comparison pattern; and
ascertaining an existence of a connect ion of the respective bonding pad to the external circuit from comparison results.

10. The method according to claim 8, which comprises:
checking a predetermined number of the bonding pads for a connection to one of the external circuits; and
carrying out a data exchange through the bonding pads which have been identified as being connected to one of the external circuits.
